(19) United States
(12) Patent Application Publication
(10) Pub. No.: US 2026/0096020 A1
(43) Pub. Date: Apr. 2, 2026

(54) CIRCUIT BOARD FOR INSTALLATION IN AN ELECTRICAL DEVICE

(71) Applicant: Drägerwerk AG & Co. KGaA, Lübeck (DE)

(72) Inventors: Markus HAMPE, Lübeck (DE); Robert LISCHINSKI, Lübeck (DE); Michael GEY, Lübeck (DE); Frank MARQUARDT, Lübeck (DE)

(21) Appl. No.: 19/346,799

(22) Filed: Oct. 1, 2025

(30) Foreign Application Priority Data
Oct. 2, 2024 (DE) 10 2024 128 498.6

(51) Int. Cl. H05K 1/02

(52) U.S. Cl. CPC H05K 1/0277; H05K 2201/09027

(57) ABSTRACT

A circuit board (100), for installation in an electrical device (500), includes a flexible bending section (110), a plurality of conductor tracks (112) arranged in the flexible bending section with a first number of conductor tracks (114) arranged in a first leg (115) and a second number of conductor tracks (114′) arranged in a second leg (115′). The first leg is parallel to the second leg and an open region (116) between the two legs spatially separating the two legs from one another. At least two rigid interface sections (120, 130) are arranged and configured to be electrically connected to one another via the conductor tracks. The two legs fold towards one another about a folding axis (118) along the open region reducing an installation width (EB) of the flexible bending section in the electrical device compared with a width (B) in an unfolded state.

### CROSS REFERENCE TO RELATED APPLICATIONS

This application claims the benefit of priority under 35 U.S.C. § 119 of German Application 10 2024 128 498.6, filed Oct. 2, 2024, the entire contents of which are incorporated herein by reference.

### TECHNICAL FIELD

The invention relates to a circuit board for installation in an electrical device (electrical appliance). Such a circuit board can be realized and/or described as a printed circuit board (PCB), a flexible circuit board, a flexible PCB, a flexible cable line, and a ribbon cable. The invention also relates to an electrical device and a process for manufacturing a circuit board for installation in an electrical device.

### BACKGROUND

In principle, many different structures for circuit boards are known. In particular, the provision of flexible bending sections is also known in order to connect rigid sections of the circuit board to each other via conductor tracks (conductive paths) within the bending section. Such a bending section typically consists of a thin plastic layer that surrounds the conductor tracks. It is also known that circuit boards can have one or more rigid interface sections in order to connect the circuit board to other components of the corresponding electrical device. As a result, the circuit board forms at least a part of a circuit of the electrical device. In this sense, a circuit board can have rigid and flexible sections and can therefore also be partially folded, bent or dynamically modified in other ways, for example to enable movement of components of the electrical device connected via the circuit board.

### SUMMARY

It is an object of the invention to provide an improved circuit board, in particular a particularly compact and robust circuit board.

In accordance with a first aspect of the invention, to achieve this object, a circuit board, in particular a flat circuit board, for installation in an electrical device is provided, including
at least one flexible bending section, wherein a plurality of conductor tracks is arranged in the flexible bending section in such a way that a first number of conductor tracks is arranged in a first leg of the flexible bending section and that a second number of conductor tracks is arranged in a second leg of the flexible bending section, wherein the first leg is arranged parallel to the second leg and an open region between the two legs spatially separates the two legs from each other,
at least two rigid interface sections which are arranged and configured to be electrically connected to one another via the plurality of conductor tracks and to provide a respective interface with a device component of the electrical device, so that at least two device components of the electrical device can be electrically connected to one another by the circuit board,
   wherein the two legs can be folded relative to one another about at least one folding axis located along the open region in order thereby to reduce, in particular substantially halve, an installation width of the flexible bending section for installation in the electrical device compared with a width in an unfolded state of the flexible bending section.

In the context of the invention, it was recognized that the housings of movable electrical devices sometimes provide little space for the arrangement of the circuit board, so that a compact and yet reliably usable circuit board with at least one bending section can be particularly advantageous for many applications. Compact dimensions are achieved, for example, by folding, wherein it has also been recognized that it is particularly advantageous to fold along an open area so that no unnecessary curvature of conductor tracks occurs. In this way, a particularly robust circuit board can be advantageously achieved despite the folding within the bending section.

The circuit board according to the invention can therefore ensure a particularly reliable electrical connection between two device components of the electrical device that can move relative to each other.

The circuit board is advantageously configured to control at least one of the two device components and/or support a corresponding control system, for example by means of a power supply.

Preferably, the circuit board is a flat circuit board, i.e. a circuit board with a circuit board plane along which essentially all sections of the circuit board are arranged.

The electrical device is preferably a medical device. The robust design of the circuit board according to the invention and the resulting high functional reliability are particularly advantageous for medical devices. As is known, the electrical device has a power supply through which the circuit board can be supplied with power. Such a supply can, for example, be provided via at least one of the at least two rigid interface sections.

The plurality of conductor tracks preferably comprises at least two conductor tracks in the first leg of the bending section and at least two conductor tracks in the second leg of the bending section. Preferably, the conductor tracks of the plurality of conductor tracks are at least partially connected to each other via a plastic and thus preferably form a PCB (printed circuit board) plane (circuit board level) of the circuit board. The use of a plurality of conductor tracks makes it possible to transmit a multitude of signals in parallel.

The respective rigid interface section forms an interface for an external connection area of an electronic system of the electrical device via a respective connection area. In addition, a plug connection within a circuit of the electrical device can be provided via a respective interface section, for example.

According to the invention, the circuit board consists of rigid and flexible areas and as such does not form a completely rigid board. Therefore, the term circuit board rather refers to the function of this component within an electronic system of the electrical device, in which the circuit board has a central task for connecting and/or controlling components. The transition between the flexible bending section and a rigid section, such as the rigid interface section, is known for the manufacture of circuit boards (PCBs), so that details of this rigid section manufacture will not be discussed in detail below.

Preferred embodiments of the circuit board according to the invention are described below.

In a particularly preferred embodiment, the circuit board according to the invention further comprises a rigid fixing section which is arranged and configured to connect a first flexible bending section of the circuit board, which comprises the first and second legs, to a second flexible bending section of the circuit board, so that the first flexible bending section can be moved independently of the second flexible bending section by fixing the rigid fixing section. In this embodiment, the two flexible bending sections enable great mobility between the at least two rigid interface sections and the rigid fixing section, which is preferably located between two interface sections. Thus, the at least two interface sections are preferably electrically connected to each other via the fixing section. Movement is possible between a first interface section and the fixing section and between the fixing section and a second interface section. The circuit board for an electrical device can therefore enable rotation about several axes simultaneously. The rigid fixing section can also be used to reliably fix a position of the at least two bending sections connected to the fixing section within the electrical device, which enables a particularly robust structure of the electrical device, in particular a structure without loosely hanging bending sections.

In a preferred variant of the preceding embodiment, the first and second flexible bending sections extend from the fixing section in different directions. Different directions are, for example, different directions relative to a conductor track direction within the rigid fixing section. In this way, a spatial structure of the circuit board can be advantageously adapted to a housing structure of the electrical device.

In a preferred embodiment, the at least two rigid interface sections are aligned in at least two different directions in a flat arrangement of the circuit board. This allows the circuit board to be advantageously adapted to different surrounding geometries of the surrounding electrical device. For example, the different orientations can enable a bending section to be folded, thereby changing the orientation of a bending axis of the bending section, as described in FIG. 4

In a further preferred embodiment, the first and second legs have a different length, wherein a resulting difference in length can be compensated for by a further fold, in particular a further fold essentially perpendicular to the fold axis of the two legs, for installation in the electrical device. An example of such a fold is shown in FIG. 4 and FIG. 5. Such a fold can, for example, enable the corresponding rigid interface section and/or the fixing section to be tilted by a fixed angle, such as an angle of essentially 90°, relative to the partially folded bending section.

In a particularly preferred embodiment, the plurality of conductor tracks is arranged in the flexible bending section in such a way that the conductor tracks are bent essentially perpendicular to a rolling direction of the conductor tracks (of rolled copper). Such an orientation of the bend is particularly advantageous because the rolling direction of typically used copper conductor tracks has a great influence on the bending strength and thus the breaking strength of the bending section of the circuit board. Areas subject to bending stress are more robust if the corresponding bending axis is arranged perpendicular to the rolling direction.

In an advantageous variant of the previous embodiment, the rolling direction is essentially along the folding axis of the two legs. As a result, the two folded legs can be rolled up in the installed state to enable rotation of two device components of the electrical device.

In principle, the circuit board can comprise a robust power line between at least two device components of the electrical device and/or control electronics for controlling at least parts of the electrical device.

According to a second aspect of the invention, an electrical device having a circuit board according to at least one of the preceding embodiments is provided for solving the above-mentioned problem, wherein the at least one flexible bending section is at least partially bent by a relative movement of the at least two device components of the electrical device with respect to each other, and wherein this bending is limited by at least one guide rail within a housing of the electrical device that cooperates with and/or is formed by one or both of the device components.

The electrical device according to the second aspect of the invention comprises the circuit board according to the first aspect of the invention and thus also all the advantages of this circuit board. In particular, the circuit board enables a particularly compact configuration of the electrical device in the area of the circuit board due to its folded bending section in the installed state. In addition, the bendability and the targeted folding in the open area enable a robust installation arrangement of the circuit board in the electrical device. Finally, the provision of the guide rail within the housing, preferably directly on the housing of the electrical device, enables a reliable specification of an area within the housing in which the bending section of the circuit board can be contained.

In addition to the guide rail, other guide elements, such as individual guide pins, guide walls or the like, can limit the movement of the flexible bending section within the housing. This is an advantageous way of limiting the bending radius, for example, as described in FIG. 5. The routing of the conductor tracks within the housing of the electrical device also ensures a particularly robust configuration, which prevents cables from being accidentally pulled out. A device component of a user interface of the electrical device connected to the circuit board is particularly preferred. Based on the bendability of the circuit board, this can support the mobility of the user interface, for example to increase user comfort.

In a particularly preferred embodiment, the relative movement of the at least two device components to each other comprises a rotary movement and/or a tilting movement. These types of motion allow a particularly precisely predetermined form of motion, so that the circuit board can withstand many motion cycles without sustaining damage in the moving bending section. Rotational movements and tilting movements also allow a particularly smooth and reversible movement, so that even a robust electrical device can allow such movements. In a variant of the preceding embodiment, the rigid fixing section is also provided between two flexible bending sections in the circuit board, wherein the first flexible bending section enables rotation of the rigid fixing section relative to a rigid interface section as part of the rotating movement, and wherein the second flexible bending section enables tilting of the rigid fixing section relative to a further rigid interface section as part of the tilting movement. In this embodiment, the advantage of providing two bending sections is evident, as these allow different movements to be performed simultaneously. In this way, a device component, such as a user interface, for example a touch display of the electrical device, can be tilted and rotated particularly freely via the circuit board without damaging its power supply over time.

In a preferred example of the previous variant, the circuit board is arranged in such a way that a rotation axis of the rotary movement is perpendicular to a tilting axis of the tilting movement. Due to such an arrangement of axis of rotation and tilt axis, the corresponding device component can be moved particularly freely in space, so that a device component position can be advantageously adapted to the individual needs of the user of the electrical device.

For example, the electrical device can be a medical device whose user interface, such as its touch display, can be freely adapted to a current treatment situation.

In an advantageous embodiment of the electrical device according to the invention, an angle clamp, in particular a reversibly fastenable angle clamp, is arranged on at least one flexible bending section perpendicular to the corresponding conductor tracks in order to keep a predetermined angle constant between a conductor track section leading to the angle clamp and a conductor track section leading away from the angle clamp. The use of such an angle clamp is advantageous because it allows the predetermined angle to be fixed once, so that the conductor tracks in this area are not constantly bent back and forth, which can lead to breakage. Such a predetermined angle can be advantageous for the implementation of a tilting movement between two device components, as only small angular differences must be available for a tilting movement compared to a rotary movement. Thus, a tilting movement can preferably comprise an angular range of less than 90°, in particular of less than 80°, especially preferably of about 75° between a first and a second tilting limit. A turning movement can preferably comprise an angular range of less than 360°, in particular of less than 270°, particularly preferably of about 200° between a first and a second turning limit.

In a preferred variant, the predetermined angle of the angle clamp is at least 30°, preferably at least 45°, particularly preferably at least 60°. Such a predetermined angle can protect the remaining areas of the conductor tracks of this bending section from strong bending. As a result, bending stresses that promote breakage can be avoided. For example, such a predetermined angle with an angle range of less than 90°, in particular less than 80°, especially preferably about 75°, can ensure that only a very slight tilting of the conductor tracks outside the angle clamp is necessary in the case of a medium tilting. In this way, the angle clamp in this variant can particularly reliably increase the durability of the circuit board within the electrical device.

In a further embodiment, the at least one flexible bending section enables a floating bearing (floating mounting/floating support) of at least one rigid interface section connected to the flexible bending section along an extension direction of the flexible bending section. During a tilting movement, a distance of the rigid interface section from the tilting axis can change slightly, so that the floating bearing by the flexible bending section avoids tension within the conductor tracks. In this embodiment, the floating bearing supports a long service life of the electrical device according to the invention.

According to a third aspect of the invention, a process of manufacturing a circuit board is proposed for solving the above-mentioned problem. The process comprises the steps of:
Arranging a plurality of conductor tracks in a flexible bending section, so that a first number of conductor tracks is arranged in a first leg of the flexible bending section and that a second number of conductor tracks is arranged in a second leg of the flexible bending section, the first leg being arranged parallel to the second leg and an open region between the two legs spatially separating the two legs from one another;
Arranging at least two interface sections on the at least one flexible bending section such that the at least two interface sections are electrically connected to each other via the plurality of conductor tracks and provide a respective interface with a device component of the electrical device, so that at least two device components of the electrical device can be electrically connected to each other by the circuit board; and
Folding the two legs towards each other about at least one folding axis located along the open area, in order to thereby reduce, in particular substantially halve, an installation width of the flexible bending section for installation in the electrical device compared to a width in an unfolded state of the flexible bending section.

The process according to the invention is carried out when providing and installing the circuit board according to the first aspect of the invention, so that the process has the corresponding advantages of the circuit board. In particular, the process according to the third aspect of the invention enables particularly compact dimensions of the installed circuit board due to the folding along the folding axes for installation in the electrical device.

Preferably, the last folding step is carried out after the first two steps. The first two steps are carried out during a manufacturing process of the circuit board, while the last step of folding can also be carried out later, particularly during a subsequent assembly process of the electrical device.

From the above-mentioned embodiments of the circuit board and the electrical device, it is disclosed to the skilled person that the process according to the invention can be supplemented by further steps while remaining a process according to the invention. For example, the process can be supplemented by arranging the angle clamp on a bending section. Alternatively, or additionally, the process can be supplemented, for example, by a folding at a bending section of the circuit board for length compensation of two legs of different lengths of the corresponding bending section.

The invention will now be explained in more detail with reference to advantageous embodiments shown schematically in the figures. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 is a schematic view of a first embodiment of a circuit board according to a first aspect of the invention;

FIG. 2 is a schematic view of a second embodiment of the circuit board according to the first aspect of the invention;

FIG. 3 is a schematic view of a third embodiment of the circuit board according to the first aspect of the invention;

FIG. 4 is a perspective view of a fold of the circuit board according to the third embodiment of the circuit board;

FIG. 5 is a perspective view of a first embodiment of an electrical device according to a second aspect of the invention with a built-in circuit board according to the first aspect of the invention;

FIG. 6 is a perspective sectional view of a second embodiment of the electrical device according to the second aspect of the invention;

FIG. 7 is a detailed view of the second embodiment of the electrical device shown in FIG. 6; and

FIG. 8 is a flowchart of an embodiment of a process according to a third aspect of the invention.

### DESCRIPTION OF PREFERRED EMBODIMENTS

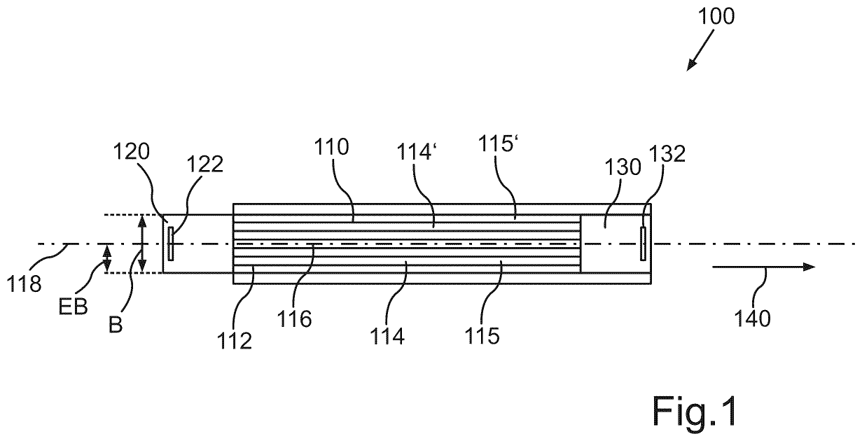

Referring to the drawings, FIG. 1 shows a schematic representation of a first embodiment of a circuit board 100 according to a first aspect of the invention. In the present case, the circuit board 100 is configured as a flat circuit board 100 and is intended for installation in an electrical device. For this purpose, it comprises at least one flexible bending section 110 and at least two rigid interface sections 120, 130. In the at least one flexible bending section 110, a plurality of conductor tracks 112 is arranged in such a way that a first number of conductor tracks 114 is arranged in a first leg 115 of the flexible bending section 110 and that a second number of conductor tracks 114′ is arranged in a second leg 115′ of the flexible bending section 110. The first leg 115 is arranged parallel to the second leg 115′. In the present case, the circuit board comprises exactly one bending section with exactly the two legs 115, 115′. According to the invention, there is an open area 116 between the two legs 115, 115′ which spatially separates the two legs 115, 115′ from one another.

In the present case, this open area is formed as an elongated slot. In embodiments of the invention not shown, the open area also has other shapes. The illustrated embodiments with an elongated slit share the advantage that such a slit can be produced particularly easily and inexpensively during the manufacturing process by two legs 115, 115′ to be manufactured and attached separately.

In FIG. 1, three conductor tracks 114, 114′ are arranged in each leg 115, 115′ as an example. These conductor tracks 114, 114′ are preferably integrated into the bending section 110 in such a way that they cannot be seen from the outside and/or that they are encased from the outside. For reasons of clarity, these conductor tracks are not shown in the following embodiment examples.

The at least two rigid interface sections 120, 130 are arranged and configured to be electrically connected to each other via the plurality of conductor tracks 112 and to provide a respective interface 122, 132 with a device component of the electrical device, so that at least two device components of the electrical device can be electrically connected to each other by the circuit board 100. In the present case, the two rigid interface sections 120, 130 are configured to provide a respective plug connection with the device components not shown in FIG. 1 for reasons of clarity

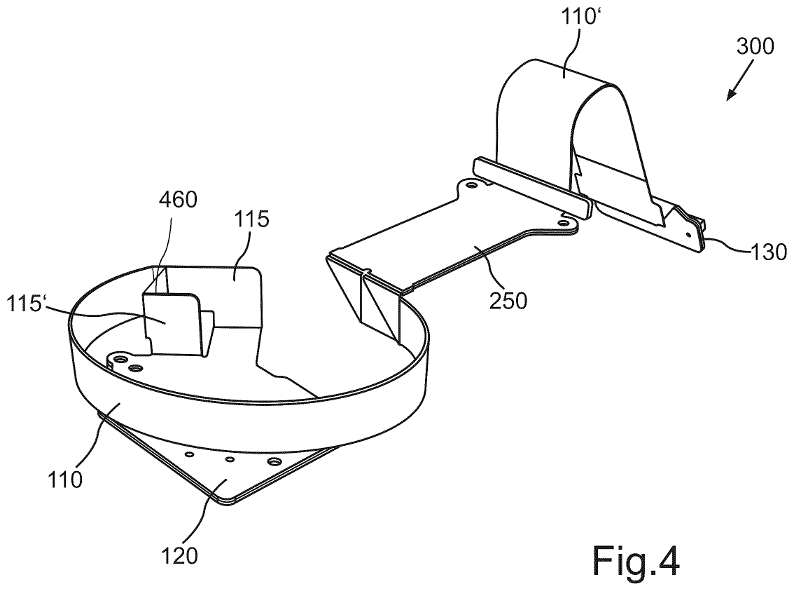

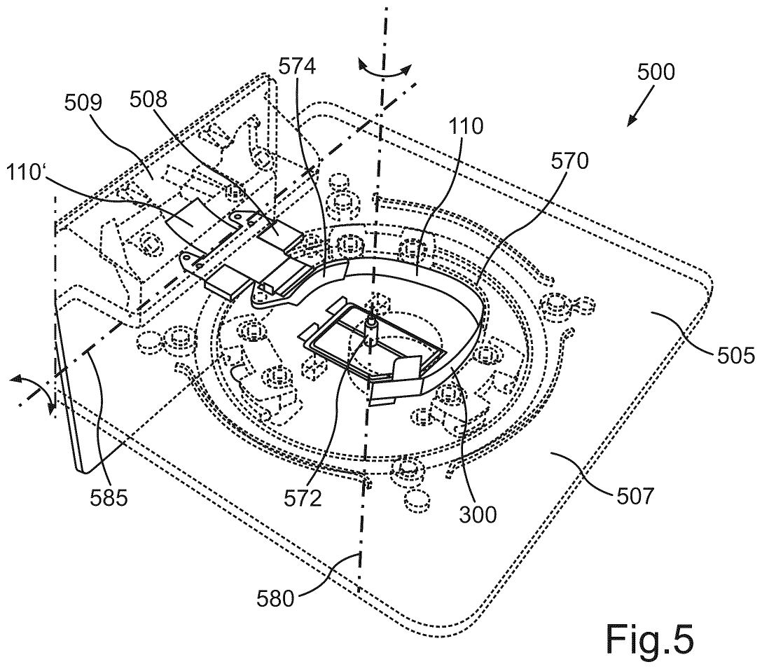

According to the invention, the two legs 115, 115′ can be folded towards each other about a folding axis 118 located along the open area 116. As a result, an installation width EB of the flexible bending section 110 for installation in the electrical device can be reduced compared to a width B in an unfolded state of the flexible bending section 110. In the present case, due to the rigid interface sections 120, 130, the installation width can only be partially reduced if the bending section 110 sags in the installed state, thereby also enabling partial folding of the two legs 115, 115′ relative to one another. In this case, the installation width EB of the bending section 110 can be essentially halved. Alternative examples of folding can be seen, for example, in FIGS. 4 and 5. In the illustrated embodiment example of the circuit board 100, a movement of the rigid interface sections 120, 130 relative to one another can be achieved, for example, by tilting these rigid interface sections 120, 130 relative to one another. In the context of such tilting, the bending section 110 would be bent in such a way that the bending of the conductor tracks 114, 114′ is essentially perpendicular to a rolling direction 140 of the conductor tracks 114, 114′. This can advantageously ensure a durability of the conductor tracks 114, 114′, which typically consist of copper (rolled copper), even with repeated bending, since the bending strength of a respective conductor track 114, 114′ perpendicular to the rolling direction is particularly high. The reason for this lies in the copper foil structure, which assumes an elongated-oval shape as a result of the rolling process and thus have a particularly closed structural bond with one another in the rolling direction 140. In view of the arrangement of the rolling direction 140 for the conductor tracks 114, 114′, this rolling direction 140 is essentially formed along the folding axis 118 of the two legs 115, 115′.

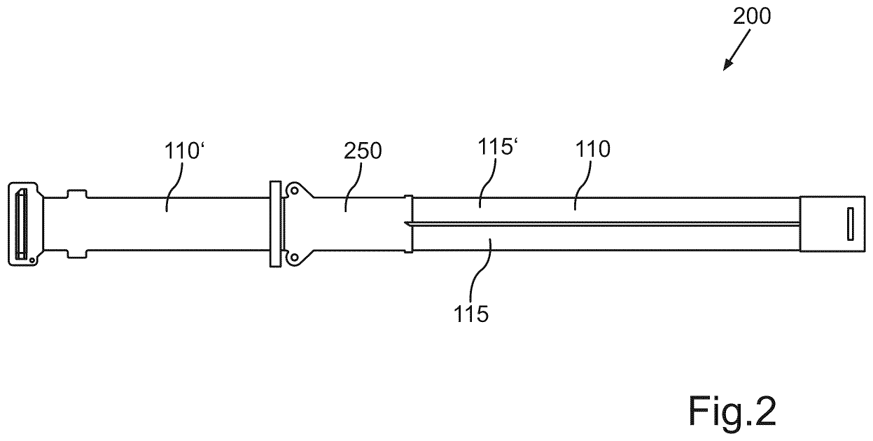

FIG. 2 shows a schematic representation of a second embodiment of the circuit board 200 according to the first aspect of the invention.

The circuit board 200 substantially corresponds to the circuit board 100 shown in FIG. 1, wherein the circuit board 200 further comprises a rigid fixing section 250 which is arranged and configured to connect a first flexible bending section 110 of the circuit board 200, which comprises the first and second legs 115, 115′, to a second flexible bending section 110′ of the circuit board 200. By providing the fixing section 250, the first flexible bending section 110 can be moved independently of the second flexible bending section 110′ after the rigid fixing section 250 has been fixed. This means that two movements can take place simultaneously. Just as with the circuit board 100 shown in FIG. 1, the circuit board 200 is arranged flat by the two flexible bending sections 110, 110′

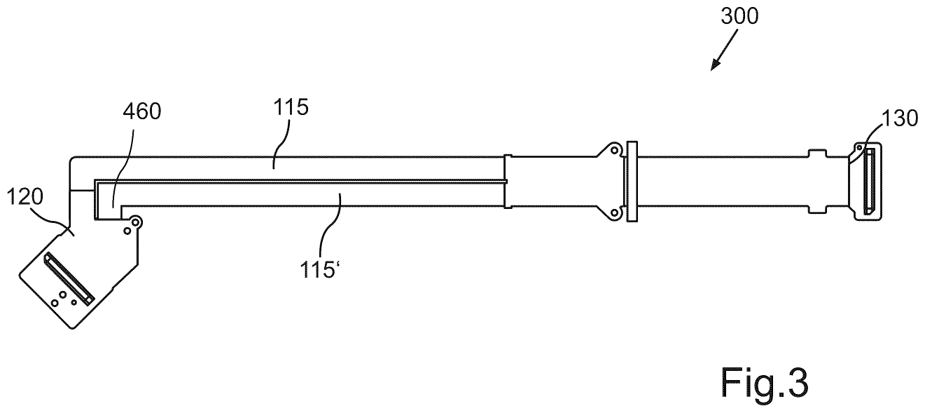

FIG. 3 shows a schematic representation of a third embodiment of the circuit board 300 according to the first aspect of the invention. The circuit board 300 according to FIG. 3 is formed similarly to the circuit board 200 shown in FIG. 2, wherein the at least two rigid interface sections 120, 130 are aligned in at least two different directions in a planar arrangement of the circuit board 300. How this asymmetry affects the possible spatial arrangement in an electrical device is shown, for example, in FIG. 4. FIG. 3 also shows that the first and second legs 115, 115′ have different lengths. In addition, the conductor tracks in both legs are guided around a respective corner of the leg 115, 115′.

FIG. 4 shows a perspective view of a folding of the circuit board 300 according to the third embodiment example.

In the folded state, the difference in length shown in FIG. 3 is compensated for by a further fold 460, in particular a further fold 460 substantially perpendicular to the fold axis 118 of the two legs 115, 115′, for installation in the electrical device. The further fold 460 has a Z-shape (FIG. 4). The Z-shape can be used, for example, to compensate for length during a rotary movement, as can be seen in FIG. 5.

Finally, it is shown in FIG. 4 that the first bending section 110 and the second bending section 110′ can extend in different directions starting from the fixing section 250. As a result, the first bending section 110 can be bent in a different direction than the second bending section 110′ if one wishes to limit oneself to a bending perpendicular to the rolling direction of the conductor tracks in order to support the durability of the circuit board. The design of the rigid interface sections 120, 130 and the fixing section 250 are obviously exemplary in the illustrated embodiments and can always be adapted to a respective electrical device. In addition, more than two interface sections for the circuit board according to the invention are possible in embodiments not shown. Furthermore, in embodiments not shown, it is possible to connect more than two device components via the circuit board for the electrical device according to the invention.

FIG. 5 shows a perspective view of a first embodiment of an electrical device 500 according to a second aspect of the invention with a built-in circuit board 300 according to the first aspect of the invention. The circuit board 300 is the circuit board 300 already shown in FIG. 3 and FIG. 4. The electrical device 500 is a medical device in the present case. The installation situation shown illustrates the advantage of two bending sections 110, 110′, since two different movements along different axes are made possible in the electrical device 500. Thus, the first flexible bending section 110 is limited in its possible movement by at least one guide rail 570 within a housing 505 of the electrical device 500. The guide rail 570 is thereby curved and ensures that the bending radius of the first flexible bending section 110 does not become too small, in order to extend the service life of the conductor tracks within the flexible bending section. Thus, a first device component 507 of the electrical device 500 can be moved relative to a second device component 509 of the electrical device 500 along multiple axes while the circuit board 300 according to the invention electrically connects these two device components 507, 509 together.

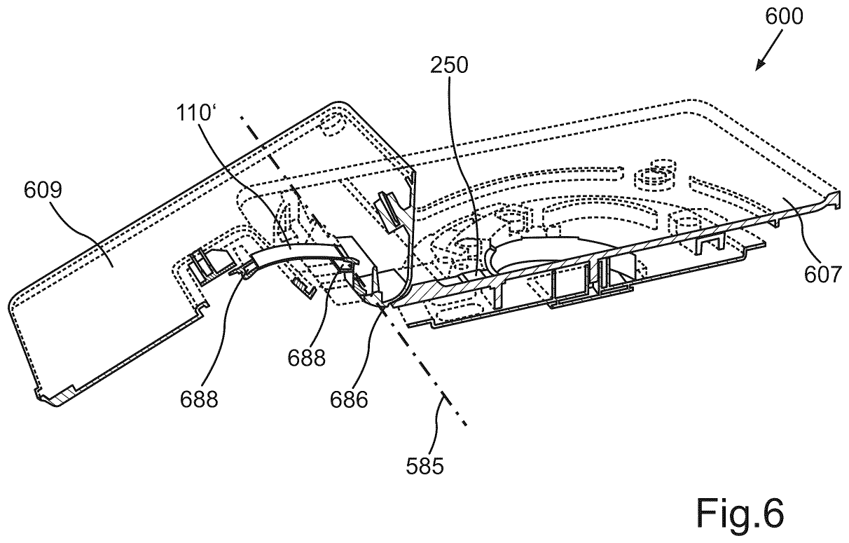

A first movement is made possible by a rotation axis 580 of the rotary movement, during which the first flexible bending section 110 can be at least partially rolled up and unrolled again. Preferably, a rotation about the axis of rotation 580 of less than 360°, in particular of less than 270°, particularly preferably of about 200° between a first and a second rotation limit is possible. The second flexible bending section 110′ also enables a tilting movement of the second device component 509 relative to the first device component 507 about a tilting axis 585. This tilting is shown in more detail in FIG. 6 for a similar embodiment. Thus, the two flexible bending sections 110, 110′ enable a movement of the second device component 509 relative to the first device component 507 about two different axes, wherein in this case the tilting axis 585 is formed perpendicular to the axis of rotation 580

The illustrated arrangement of the circuit board 300 in the electrical device 500 can ensure a limitation of the bending radius and/or prevention of a bending change via the guide rail 570, which in this case projects from the housing 505 into an interior of the device, and further movement limiting means, such as a stop. In addition to the guide rail 570, a guide pin (mandrel) 572 is also provided for this purpose, which additionally limits the winding of the first flexible bending section. A further guide means in the illustrated electrical device 500 is a guide rib 574 in the region of the rigid fixing section 250, which predetermines a bend and can thus reliably prevent an accidental bending change of the first flexible bending section. Such guide means can advantageously support a reduction of a risk of failure of the circuit board 300.

In the present case, the fixing section 250 is attached to an intermediate component 508 of the electrical device 500, which can be moved relative to the first device component 507 and to the second device component 509. In the case of pure rotation about the rotation axis 580, the intermediate component 508 is immovable relative to the second device component 509. In the case of pure tilting about the tilting axis 585, the intermediate component 508 is immovable relative to the first device component 507.

FIG. 6 shows a perspective sectional view of a second embodiment of the electrical device 600 according to the second aspect of the invention. The electrical device 600 substantially corresponds to the electrical device 500 shown in FIG. 5, wherein the second flexible bending section 110′ is shown in detail for the electrical device 600. The second flexible bending section 110′ enables the second device component 609 to be tilted relative to the first device component 607 about the tilting axis 585. In order to specify a direction of curvature and to limit the radius of curvature, the housing 605 of the electrical device has a guide track 686 in the region of the rigid fixing section 250 on the second flexible bending section 110′. In addition, an angle clamp 688, in particular a reversibly fixable angle clamp 688, is arranged on the second flexible bending section 110′ perpendicular to the corresponding conductor tracks in order to keep a predetermined angle constant between a conductor track section leading towards the angle clamp 688 and a conductor track section leading away from the angle clamp 688. In the illustrated embodiment example, two such angle clamps 688 are provided. The angle predetermined by the respective angle clamp 688 is at least 30°, preferably at least 45°, particularly preferably at least 60°. The predetermined angle ensures that the conductor tracks in this area are no longer additionally bent, so that the probability of failure of the conductor tracks in the area of the angle clamp is low. In particular, changes in bending are avoided. Such an angle clamp 688 is particularly advantageous in cases in which there is always a strong bend in a basic position of the second device component 609, so that the angle clamp 688 can reduce this bend in the basic position at least outside the angle clamp. In the present case, the angle clamp 688 can be reversibly locked via a positive locking mechanism. This makes it particularly easy to attach during the manufacturing process of the circuit board 300 and/or the assembly process of the electrical device 600. The possible angle of tilt about the tilting axis 585 preferably comprises an angular range of less than 90°, in particular of less than 80°, particularly preferably of about 75° between a first and a second tilting limit.

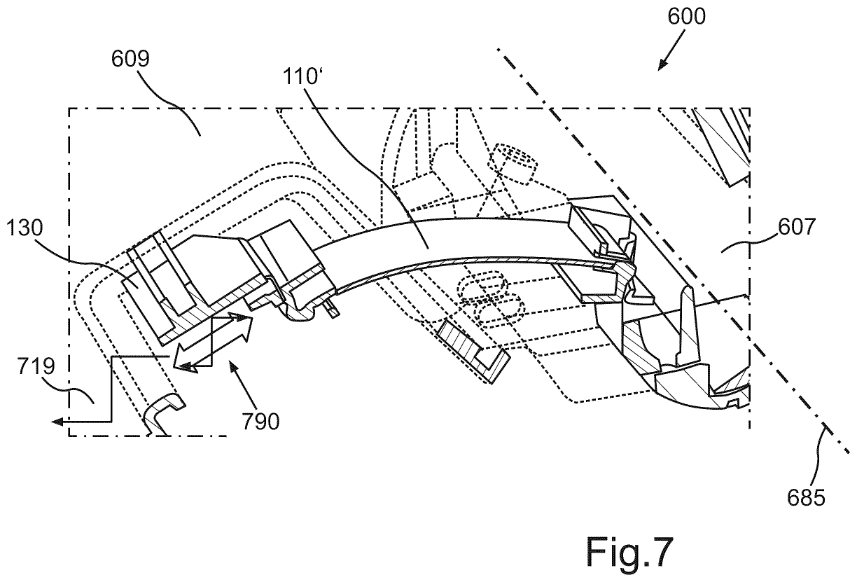

FIG. 7 shows a detailed representation of the second embodiment of the electrical device 600 of FIG. 6. This detailed representation illustrates a floating bearing 790 of the second rigid interface section 130 on the second device component 609 along an extension direction 719 of the second flexible bending section 110′. This floating bearing 790 is advantageous because a distance between the second rigid interface section 130 and the tilting axis 685 can be changed during tilting, and thus additional forces could be applied to the interface section 130 without such a bearing. Therefore, the floating bearing 790 supports the durability of the electrical device even with frequent tilting and rotation of the second device component 609 relative to the first device component 607. In principle, the electrical devices 500, 600 shown are merely exemplary. In particular, the provision of a single bending section, as shown for example in FIG. 1, obviously also leads to a circuit board according to the invention and consequently also to an electrical device according to the invention, if this circuit board is installed accordingly in the electrical device.

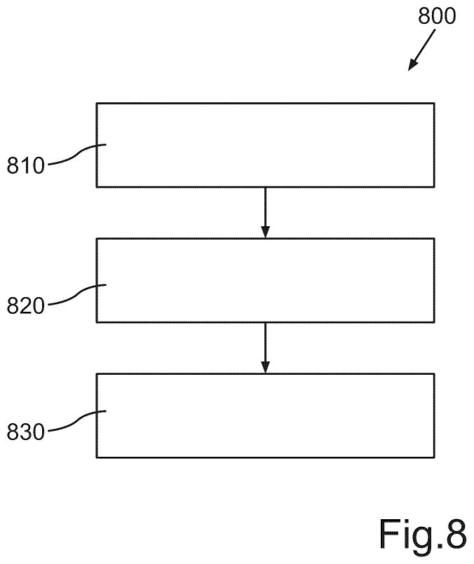

FIG. 8 shows a flow diagram of an embodiment of a process 800 according to a third aspect of the invention. The process 800 according to the invention is configured to manufacture a circuit board. For this purpose, it comprises the steps described below.

A first step 810 comprises arranging a plurality of conductor tracks in a flexible bending section such that a first number of conductor tracks are arranged in a first leg of the flexible bending section and that a second number of conductor tracks are arranged in a second leg of the flexible bending section, wherein the first leg is arranged parallel to the second leg and an open area between the two legs spatially separates the two legs.

A next step 820 comprises arranging at least two interface sections on the at least one flexible bending section such that the at least two interface sections are electrically connected to each other via the plurality of conductor tracks and provide a respective interface with a device component of the electrical device, such that at least two device components of the electrical device can be electrically connected to each other through the circuit board.

A final step 830 comprises folding the two legs with respect to each other about a folding axis located along the open region, thereby reducing, in particular substantially halving, an installation width of the flexible bending section for installation in the electrical device compared to a width in an unfolded state of the flexible bending section. The steps 810 and 820 are preferably carried out in any order as part of the manufacture of the circuit board. The step 830 of folding the two legs takes place after the two steps 810 and 820. The step 830 can also take place when the circuit board is installed in the electrical device, for example during an assembly process of the electrical device. In principle, the process 800 according to the invention can also be supplemented by further steps, such as the arrangement of at least one fixing section, the additional folding of at least one leg of the bending section and/or the arrangement of at least one angle clamp on a bending section or the like. Such additions to the process according to the invention result directly from the embodiments described for the circuit board and the electrical device.

While specific embodiments of the invention have been shown and described in detail to illustrate the application of the principles of the invention, it will be understood that the invention may be embodied otherwise without departing from such principles.

List of reference symbols

| | |
|---|---|
| 100, 200, 300 | Printed circuit board |
| 110 | First flexible bending section |
| 110′ | Second flexible bending section |
| 112 | Plurality of conductor tracks |
| 114 | First number of tracks |
| 114′ | Second number of tracks |
| 115 | First leg |
| 115′ | Second leg |
| 116 | Open area |
| 118 | Folding axis |
| 120 | First rigid interface section |
| 122 | Interface of the first rigid interface section |
| 130 | Second rigid interface section |
| | Interface of the second rigid interface section |
| 140 | Rolling direction |
| 250 | Fixing section |
| 460 | Further folding |
| 500, 600 | Electrical device |
| 505 | Housing |
| 507, 607 | First device component |
| 508 | Intermediate component |
| 509, 609 | Second device component |
| 570 | Guide rail |
| 572 | Guide pin |
| 574 | Guide rib |
| 580 | Rotation axis |
| 585 | Tilting axis |
| 686 | Guide track |
| 688 | Angle clamp |
| 719 | Extension direction of the second flexible bending section |
| 790 | Floating bearing |
| 800 | Procedure |
| 810, 820, 830 | Process steps |
| EB | Installation width |
| B | Width |

What is claimed is:

1. A circuit board for installation in an electrical device, the circuit board comprising:
a flexible bending section, the flexible bending section comprising a plurality of conductor tracks arranged in the flexible bending section such that a first number of conductor tracks is arranged in a first leg of the flexible bending section and such that a second number of conductor tracks is arranged in a second leg of the flexible bending section, wherein the first leg is arranged parallel to the second leg and an open region between the two legs spatially separates the first legs from the second leg; and
at least two rigid interface sections arranged and configured to be electrically connected to each other via the plurality of conductor tracks and to provide a respective interface with a device component of the electrical device, such that at least two device components of the electrical device can be electrically connected to each other by the circuit board,
wherein the two legs are configured to be folded towards one another about at least one folding axis located along the open region, to reduce an installation width of the flexible bending section in an installed state in the electrical device compared with a width in an unfolded state of the flexible bending section.

2. A circuit board according to claim 1, wherein the two legs are folded towards one another about the at least one folding axis to form a folded installation configuration that is substantially half the width in the unfolded state of the flexible bending section.

3. A circuit board according to claim 1, further comprising:
a second flexible bending section; and
a rigid fixing section arranged and configured to connect the flexible bending section, which comprises the first leg and the second leg, as a first flexible bending section, to the second flexible bending section such that by fixing the rigid fixing section, the first flexible bending section is moveable independently of the second flexible bending section.

4. A circuit board according to claim 3, wherein the first flexible bending section and the second flexible bending section extend in different directions starting from the fixing section.

5. A circuit board according to claim 1, wherein the at least two rigid interface sections are oriented in at least two different directions in a planar arrangement of the circuit board.

6. A circuit board according to claim 1, wherein the first leg has first leg length and the second leg has a second leg length and the first leg length is different from the second leg length to provide a leg length difference and wherein the leg length difference is compensatable by a further fold.

7. A circuit board according to claim 6, wherein the further fold is substantially perpendicular to the fold axis of the two legs in an installed state in the electrical device.

8. A circuit board according to claim 1, wherein the plurality of conductor tracks is arranged in the flexible bending section such that a bending of the conductor tracks occurs substantially perpendicular to a rolling direction of the conductor tracks.

9. A circuit board according to claim 6, wherein the rolling direction is substantially along the folding axis of the two legs.

10. An electrical device comprising:
at least two device components configured for relative movement relative to each other;
at least one guide rail as a part of the at least two device components or as a part of a device housing;
a circuit board comprising: a flexible bending section, the flexible bending section comprising a plurality of conductor tracks arranged in the flexible bending section such that a first number of conductor tracks is arranged in a first leg of the flexible bending section and such that a second number of conductor tracks is arranged in a second leg of the flexible bending section, wherein the first leg is arranged parallel to the second leg and an open region between the two legs spatially separates the first legs from the second leg; and at least two rigid interface sections arranged and configured to be electrically connected to each other via the plurality of conductor tracks and to provide an interface with at least one of the at least two device components, such that the at least two device components can be electrically connected to each other by the circuit board, wherein the two legs are configured to be folded towards one another about at least one folding axis located along the open region, to reduce an installation width of the flexible bending section in an installed state in the electrical device compared with a width in an unfolded state of the flexible bending section, and wherein the at least one flexible bending section is at least partially bent by a relative movement of the at least two device components with respect to each other, and wherein this bending is limited by the at least one guide rail.

11. An electrical device according to claim 10, wherein the two legs are folded towards one another about the at least one folding axis to form a folded installation configuration that is substantially half the width in the unfolded state of the flexible bending section.

12. An electrical device according to claim 10, wherein the relative movement of the at least two device components with respect to each other comprises a rotating movement and/or a tilting movement.

13. An electrical device according to claim 12,
wherein the circuit board further comprises a second flexible bending section; and a rigid fixing section arranged and configured to connect the flexible bending section, which comprises the first leg and the second leg, as a first flexible bending section, to the second flexible bending section such that by fixing the rigid fixing section, the first flexible bending section is moveable independently of the second flexible bending section,
wherein the first flexible bending section enables rotation of the rigid fixing section relative to a rigid interface section as part of the rotating movement, and
wherein the second flexible bending section enables tilting of the rigid fixing section relative to one of the rigid interface sections as part of the tilting movement.

14. An electrical device according to claim 13, wherein the circuit board is arranged relative to the least two device components such that a rotation axis of the rotation movement is formed perpendicular to a tilting axis of the tilting movement.

15. An electrical device according to claim 10, further comprising an angle clamp arranged on the at least one flexible bending section perpendicular to the conductor tracks of the flexible bending section and configured to maintain a predetermined angle constant between a conductor track section leading to the angle clamp and a conductor track section leading away from the angle clamp.

16. An electrical device according to claim 15, wherein the angle clamp is a reversibly fastenable angle clamp, that may be fastened and unfastened.

17. An electrical device according to claim 15, wherein the predetermined angle is at least 30°.

18. An electrical device according to claim 15, wherein the predetermined angle is at least 45°.

19. An electrical device according to claim 10, wherein the at least one flexible bending section is configured to enable floating support of at least one of the rigid interface sections connected to the flexible bending section along an extending direction of the flexible bending section.

20. A process for manufacturing a circuit board for installation in an electrical device, the process comprising the steps of:
arranging a plurality of conductor tracks in a flexible bending section, such that a first number of conductor tracks is arranged in a first leg of the flexible bending section and that a second number of conductor tracks is arranged in a second leg of the flexible bending section, wherein the first leg is arranged parallel to the second leg and an open region between the two legs spatially separates the two legs from one another;
arranging at least two interface sections on the at least one flexible bending section such that the at least two interface sections are electrically connected to each other via the plurality of conductor tracks and provide a respective interface with a device component of the electrical device, such that at least two device components of the electrical device can be electrically connected to each other by the circuit board; and
folding the two legs relative to one another about at least one folding axis located along the open region, to reduce an installation width of the flexible bending section for installation in the electrical device compared with a width in an unfolded state of the flexible bending section.
